(19) United States
(12) Patent Application Publication
(10) Pub. No.: US 2018/0108526 A1
(43) Pub. Date: Apr. 19, 2018

(54) METHOD OF FORMING NANOWIRES

(71) Applicant: IMEC VZW, Leuven (BE)

(72) Inventor: Jerome Mitard, Bossut-Gottechain (BE)

(21) Appl. No.: 15/787,605

(22) Filed: Oct. 18, 2017

(30) Foreign Application Priority Data
Oct. 18, 2016 (EP) 16194382.4

(51) Int. Cl. H01L 21/02; H01L 29/06

(52) U.S. Cl. CPC H01L 21/02603; H01L 29/0673; H01L 21/02573; H01L 21/02439; H01L 29/0676; H01L 21/0242

(57) ABSTRACT

The disclosed technology generally relates semiconductor devices and more particularly to semiconductor devices comprising nanowires. In one aspect, a method of fabricating a semiconductor device includes providing a semiconductor substrate having one or more elongated structures thereon and forming a strained layer of semiconductor material on at least one surface of the elongated structures, and annealing the strained layer to form a semiconductor nanowire.

### CROSS-REFERENCE TO RELATED APPLICATIONS

This application claims foreign priority to European Patent Application No. 16194382.4, filed Oct. 18, 2016, the content of which is incorporated by reference herein in its entirety.

### BACKGROUND

### Field

The disclosed technology generally relates semiconductor devices and more particularly to semiconductor devices comprising nanowires.

### Description of the Related Technology

In a quest to maintain a scaling trend of semiconductor devices referred to as Moore's law, continuous efforts are being made to further develop the device architectures and fabrication methods of forming transistors and other semiconductor devices. A goal in this pursuit is to further scale down the device footprint of individual transistors. In order to achieve this goal, not only are endeavours being made to further decrease the dimensions of the different transistor features, such as the channel, but the industry is also increasingly moving away from classical planar device architectures. For example, the industry is increasingly investigating device architectures that employ multigate devices, such as fin field effect transistors (FinFETs). In accordance with this trend, further developments in the field may lead to the adoption of what is sometimes referred to in the industry as gate-all-around device architectures.

A limitation of some of the current device architectures is that the creation of a complementary metal-oxide-semiconductor (CMOS) device requires distinct p- and n-type FETs, which are electrically connected at the middle- or back-end-of-line (BEOL) of the semiconductor fabrication process. As such, the ability to create closely packed p- and n-type FETs which can be connected at the active device level would constitute a tremendous leap forward.

There is thus still a need within the art for better structures and fabrication methods which can enable or facilitate the use of advanced architectures, such as gate-all-around and/or closely packed p- and n-type FETs.

### SUMMARY OF CERTAIN INVENTIVE ASPECTS

It is an object of the disclosed technology to provide an improved method of forming semiconductor devices comprising nanowires.

It is an advantage of embodiments of the disclosed technology that the nanowires can be obtained in a small number of steps.

It is an advantage of embodiments of the disclosed technology that a nanowire semiconductor device can be obtained for sub-10 nm technology node, such as 7 nm technology node or even 5 nm technology node. It is a further advantage that such sub-10 nm technology node semiconductor devices may be obtained by using standard modules.

It is an advantage of embodiments of the disclosed technology that the nanowires can form part of a gate-all-around-type semiconductor device.

It is an advantage of embodiments of the disclosed technology that a plurality of nanowires can be formed on a single wall of an elongated structure or around a single elongated structure.

It is an advantage of embodiments of the disclosed technology that the individual nanowires in this plurality of nanowires can be spatially separated yet within 30 nm of one another.

It is an advantage of embodiments of the disclosed technology that some of the nanowires in this plurality of nanowires can be p-doped while others can be n-doped.

It is an advantage of embodiments of the disclosed technology that semiconductor devices comprising stacked/closely packed p- and n-doped nanowires can be obtained.

It is an advantage of embodiments of the disclosed technology that a dense pitch nanowire semiconductor device can be obtained. The final nanowire pitch depends on the initial width of an elongated structure and will thus be smaller than the elongated structure pitch. A final nanowire pitch below 10 nm or even below 7 nm may be obtained,

The above objective is accomplished by methods and devices according to the disclosed technology.

In a first aspect, the disclosed technology relates to a method for fabricating a semiconductor device, comprising the steps of:
a) providing a semiconductor substrate having one or more elongated structures thereon and a strained layer of semiconductor material on at least a surface of the elongated structures, and
b) annealing the strained layer, thereby forming a semiconductor nanowire therefrom.

In a second aspect, the disclosed technology relates to an intermediate structure in the fabrication of a semiconductor device comprising a semiconductor substrate having a plurality of parallel elongated structures thereon and a semiconductor nanowire on corresponding surfaces of each of these parallel elongated structures.

In a third aspect, the disclosed technology relates to a semiconductor device comprising a plurality of parallel nanowires wherein each nanowire is located within 30 nm, preferably within 20 nm, more preferably within 10 nm, yet more preferably within 7 nm of another nanowire.

In a fourth aspect, the disclosed technology relates to a method for fabricating a semiconductor device, comprising:
a) Providing a stack of layers comprising a strained layer of a first semiconductor material between two layers of a second semiconductor material,
b) removing part of the layers of the second semiconductor material at an extremity thereof, thereby reducing a contact area of the strained layer with the layers of the second semiconductor material, thereby freeing at least an extremity of the strained layer, said freed extremity extending from the stack, and
c) annealing the freed extremity.

In a fifth aspect, the disclosed technology relates to semiconductor device comprising a stack of layers comprising a layer of a first semiconductor material between layers of a second semiconductor material, wherein at least an extremity of the layer of a first semiconductor material extends from the stack and is rounded.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 shows a schematic representation of different lattice constants as materials are grown strained on other materials in embodiments of the disclosed technology.

FIGS. 2a and 2b are electron microscope images of structures obtained in accordance with an embodiment of the first aspect of the disclosed technology.

FIGS. 3a-3b, 4a-4b, 5a-5b, and 6a-6c schematically illustrate different embodiments of the first aspect of the disclosed technology.

FIG. 7 shows an electron microscope image of a fin fabricated according to an embodiment of the disclosed technology.

FIGS. 8 and 9 schematically illustrate different embodiments of the first aspect of the disclosed technology.

FIGS. 10a-10c illustrate an embodiment of the fourth aspect of the disclosed technology.

FIGS. 11a-11b illustrate electron microscope images of a structure according to the fifth aspect of the disclosed technology.

In the different figures, the same reference signs refer to the same or analogous elements.

### DETAILED DESCRIPTION OF CERTAIN ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, layer or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly, it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

Reference will be made to transistors. These are devices having a first main electrode such as a source, a second main electrode such as a drain and a control electrode such as a gate for controlling the flow of electrical charges between the first and second main electrodes.

The following terms are provided solely to aid in the understanding of the embodiments.

As used herein, the length (l), width (w) and thickness (t) of a three-dimensional object, such as an elongated structure, or a nanowire, are the longest, intermediate and shortest of the three dimensions of the object, respectively.

As used herein, the length (l) and width (w) of a two-dimensional object, such as a surface or a wall are the longest and shortest of the two dimensions of the object, respectively.

As used herein, a nanowire refers to a structure having a width and a thickness below about 100 nm, having the ratio of the length to the width greater than about two, and having a width/thickness ratio from about 1 to 3. More typically, the width and the thickness are below about 30 nm, yet more typically about 25 nm or below. More typically, nanowires have a length/width ratio greater than about five. More typically, the width/thickness ratio is from 1 to 2 and more typically from 1 to 1.5. As used in the relevant industry, the terms “nanoribbon”, “semiconductor wire” or “nanosheet” are used to described a nanowire having asymmetric thickness to width ratio, whereas a symmetric nanowire refers to a nanowire having equal thickness and width and thus has symmetric thickness to width ratio (i.e., 1 to 1). The nanowire may have a cylindrical shape, having a radius and a length. In the present description, the concepts and techniques described applied to nanowires can equally be applied to nanoribbons and to symmetrical nanowires. A nanowire may further be fabricated in two geometries being lateral and vertical. A lateral nanowire has a lateral orientation towards the substrate or substrate surface. It may also be referred to as horizontal nanowire. A vertical nanowire has its orientation perpendicular or vertical towards that substrate or substrate surface. The nanowire referred to in the present disclosure refers to a lateral (or horizontal) nanowire. The horizontal nanowire referred to in the present disclosure comprise two ends, one at each side of the nanowire.

As used herein, a strained layer is a layer which is deformed under the action of an applied force, or stress. In the absence of this force, e.g., at equilibrium, the layer will be in its relaxed (i.e., unstrained) state. In the context of the disclosed technology, the strained layer will typically be a strained monocrystalline layer adopting (strained) lattice constants differing from its intrinsic lattice constants (cf. infra). The deformation of the lattice is the result of a stress component applied to the material, leading to a (e.g., compressive or tensile) strain. Such an external stress occurs when the material is for example epitaxially grown on a monocrystalline surface which has at least one of its lattice constants which is different from the corresponding intrinsic lattice constants of the material making up the layer.

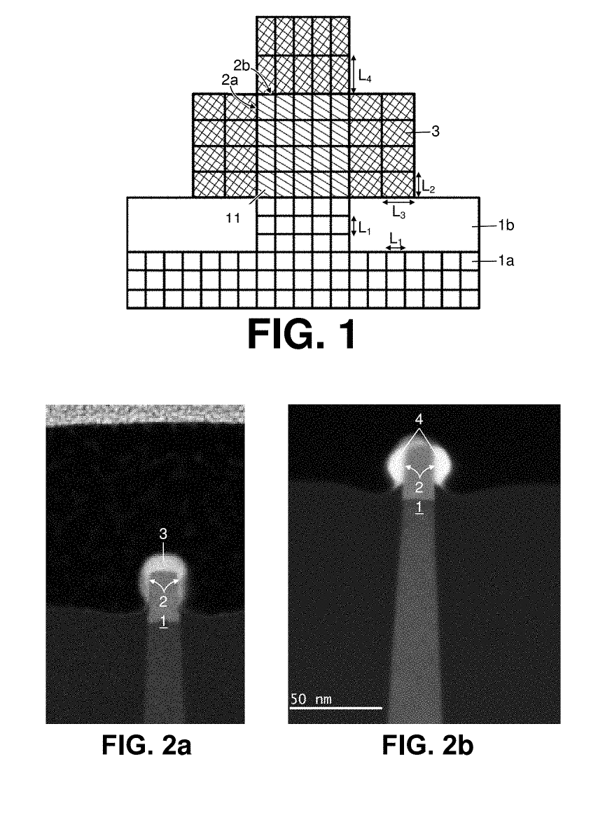

As used herein, a distinction is made between intrinsic lattice constants, i.e., the relaxed lattice constants of the material in its unstrained state, and actual lattice constants of a monocrystalline material or surface, i.e., the lattice constants of the monocrystalline material or surface as it is present in the structure of interest and which may be equal to or different from its intrinsic lattice constants. Furthermore, it should be appreciated that a material may display a different lattice constant (a, b, and c) for each of its three dimensions (X, Y and Z). Preferably, the semiconductor materials used in the disclosed technology (for the elongated structures and/or for the strained semiconductor layer epitaxially grown thereon), have a cubic crystal structure and more preferably a diamond cubic or face-centered cubic structure (e.g., as for group IV materials such as Si, Ge or SiGe and most III-V compounds). In these cases, in their relaxed state, all of the lattice constants of a particular semiconductor material are equal and the semiconductor material is said to have a single lattice constant (a). When strained however, the three lattice constants can differ. Unless otherwise indicated, a comparison of a lattice constant between different materials and/or surfaces is always performed between lattice constants in the same direction. In particular, when a further material is epitaxially grown on top of a prior material, the further material will typically adopt actual lattice constants, in the two directions parallel to its contact area with the prior material, equal to the actual lattice constants of the prior material in these two directions. In function of the difference in lattice constant between the actual lattice constants of the prior material and the intrinsic lattice constants of the further material, several situations are possible. If the two relevant intrinsic lattice constants of the further material are both smaller than the corresponding actual lattice constants of the prior material, the further material will be said to display tensile strain. If the two relevant intrinsic lattice constants of the further material are both larger than the corresponding actual lattice constants of the prior material, the further material will be said to display compressive strain. If one relevant intrinsic lattice constant of the further material in a first direction is smaller than the corresponding actual lattice constant of the prior material, and if the other relevant intrinsic lattice constant of the further material in a second direction is larger than the corresponding actual lattice constant of the prior material, the further material will be said to display tensile strain in the first direction and compressive strain in the second direction. This last situation is possible even if both the prior material and the further material have both an intrinsic cubic crystal structure if for instance the prior material was itself already strained. Indeed, if two actual lattice constants of a material are forced to adopt larger or smaller values, the material will seek to at least partially compensate the strain by adopting a respectively smaller or larger third actual lattice constant. An illustration of the concepts described in this paragraph is shown in FIG. 1 and is discussed in the examples.

In a first aspect, the disclosed technology relates to a method for fabricating a semiconductor device, comprising the steps of:
a) providing a semiconductor substrate having one or more elongated structures thereon and a strained layer of semiconductor material on at least a surface of the elongated structures, and
b) annealing the strained layer, thereby forming a semiconductor nanowire therefrom.

It was surprisingly found within the disclosed technology that upon relaxing (i.e., upon reducing and preferably suppressing the strain in) a layer of strained semiconductor material present on a substrate surface, the layer reflows (i.e., the semiconductor material rearranges spatially), while remaining in the solid state (i.e., without melting). This effect can advantageously be used to form a nanowire from the layer of semiconductor material by letting the reflow proceed until a nanowire is formed.

Without being bound to any theory, the physical mechanism behind the observed reflow of a semiconductor material is reduction or minimization of the substrate surface energy, or the semiconductor layer on the underlying semiconductor surface undergoing a change in shape to reduce or minimize its surface area.

Without being bound by any theory, the strained semiconductor material has an increased potential energy as compared to the intrinsic semiconductor material, thus relaxing the strained semiconductor material typically is a thermodynamically favourable transition. An increase in the potential energy of the semiconductor material may for example be due to a mismatch between the intrinsic lattice constants of the semiconductor material and the actual (intrinsic or strained) lattice constant of the surface it is on, which forces the semiconductor material of the layer to adopt a strained lattice and in turn increases its potential energy. Upon relaxation, the semiconductor material tends to adopt a rounder shape, while its length (l), parallel to the substrate, tends not to change significantly, thereby forming a nanowire. A rounder shape typically results in a reduced contact area with the substrate and/or an increased volume-to-surface ratio, both of which typically lead to a reduction in potential energy.

In embodiments, step a may comprise step a1 of providing a semiconductor substrate having one or more elongated structures thereon, and step a2 of growing epitaxially a strained layer of semiconductor material on at least one surface of the elongated structures.

In embodiments, step a1 may comprise step a11 of providing a semiconductor substrate and step a12 of epitaxially growing one or more elongated structures thereon.

The semiconductor substrate can be of any kind. It can be monolithic or it may be composed of different layers. It is preferable if the top surface of the substrate is monocrystalline as this permits the growth of monocrystalline elongated structures thereon, which is advantageous. Examples of suitable semiconductor substrates are Si, Ge and SiGe wafers as well as such wafers having semiconductor layers epitaxially grown thereon.

The elongated structure is a structure which is longer than it is wide. It comprises at least a surface.

In embodiments, the elongated structures may have a bottom surface in contact with the substrate, a top surface opposite to the bottom surface, two sidewalls opposite each other, a front surface and a back surface opposite the front surface.

In preferred embodiments, the elongated structure may be a fin, i.e., an elongated structure which thickness is parallel to the substrate and which width extends perpendicularly upwards from the substrate. A fin is advantageous since it comprises sidewalls separated by the smallest dimension of the fin (its thickness) thereby permitting a small distance between strained layers present thereon, thereby permitting a small distance between nanowires formed from these layers.

The elongated structure may comprise three exposed sides that are not coplanar, i.e., two side walls and a top wall. In embodiments, the side walls may be parallel or may mutually be at an angle of less than 15°. In embodiments, the elongated structure may have a length of 10 to 60 nm, preferably 15 to 50 nm, yet more preferably 15 to 40 nm. In embodiments, the elongated structure may have a width of 10 to 50 nm, preferably 10 to 40 nm, yet more preferably 10 to 25 nm. The elongated structure may have a thickness of 5 to 50 nm, preferably 5 to 30 nm, yet more preferably 5 to 15 nm. If the thickness of the elongated structure varies along its width, the structure may have a thickness, averaged along its width, of from 5 to 50 nm, preferably 5 to 30 nm, yet more preferably 5 to 15 nm. A small thickness is advantageous as it permits to have a small distance between the sidewalls of an elongated structure and therefore to a have a small distance between the nanowires formed on these sidewalls. On another hand, having a width of at least 30 nm for the top wall of an elongated structure, which is for instance the case for a fin having straight parallel side walls and a thickness of at least 30 nm, facilitates the formation of a nanowire on the top wall. The elongated structure may have a length/width ratio of 2 or more, preferably 3 or more.

In embodiments, the elongated structure may be a sacrificial elongated structure, i.e., an elongated structure which can be removed selectively with respect to the material forming the strained layer and the nanowire obtained therefrom.

The elongated structure comprises a first material forming the surface and optionally the rest of the structure. The first material is preferably a semiconductor material. In preferred embodiments, the first material is a monocrystalline semiconductor material. In embodiments, the surface of the elongated structure is preferably a monocrystalline surface. This is advantageous because it permits to grow a monocrystalline strained layer epitaxially thereon.

The first material may be unstrained in the state as it is present on the substrate but it can also be in a strained state as exemplified in FIG. 1. The first material may for example be SiₓGe_{y}, x, y<=1, for instance with y from 0.10 to 0.75 such as Si_{0.75}Ge_{0.25} or Si_{0.5}Ge_{0.5}, strained on top of Si and the semiconductor material of the layer may be Ge. In such a case, the SiGe adopts smaller lattice constants than its intrinsic lattice constants in the directions parallel to its contact area with the Si and a larger lattice constant than its intrinsic lattice constant in the direction perpendicular to its contact area with the Si (see discussion of FIG. 1 and Example 1).

In some embodiments, the surface of the elongated structure has a single lattice constant (i.e., both its lattice constants are equal, which is the case for surface 2b in FIG. 1 for instance or when the elongated structure is made of an unstrained semiconductor material with a cubic lattice).

In embodiments, the elongated structure may have at least a surface having two different lattice constants (which is the case for surface 2a in FIG. 1, for instance).

In any embodiment of the first aspect, the one or more elongated structures may be a plurality of parallel elongated structures. This permits the formation of a device comprising more than two parallel nanowires in a same plane parallel to the substrate top surface. The distance between each of these nanowires can be adapted by setting the thickness of the elongated structures and the distance between the elongated structures. The thickness of an elongated structure determines the distance between two nanowires formed on both sidewalls of that elongated structure. The distance between two adjacent elongated structures determines the distance between two adjacent nanowires supported by adjacent elongated structures. When each elongated structure has a nanowire formed on both of its sidewalls, the average distance between any two adjacent nanowires can be half the average distance between any two adjacent elongated structures. As a consequence, by adapting the distance between the elongated structures to their thickness and to the thickness of the nanowires that will form on each of their sidewalls, a regular plurality of equidistant parallel nanowires having a pitch equal to halve of the pitch of the elongated structures supporting them can be obtained. When each elongated structure has a nanowire formed on both its sidewalls, and on its top wall, the average distance between any two adjacent nanowires can be a third of the average distance between any two adjacent elongated structures. As a consequence, by adapting the distance between the elongated structures to their thickness and to the thickness of the nanowires that will form on each of their exposed walls, a regular plurality of equidistant parallel nanowires having a pitch one third of the pitch of the elongated structure supporting them can be obtained.

In any embodiment of the first aspect, the one or more elongated structures may be a plurality of parallel elongated structures, and every elongated structures may have a strained layer of semiconductor material on corresponding surfaces thereof. This permits, if the arrangement of the parallel elongated structures is regular, to form a regular arrangement of parallel nanowires with an average distance between them at least equal and in some embodiment one half or one third of the average distance between the elongated structures.

In any embodiment of the first aspect, the one or more elongated structures may be a plurality of parallel elongated structures, and every elongated structures may have a strained layer of semiconductor material on both sidewalls thereof.

In embodiments, step a may comprise providing a semiconductor substrate having one or more elongated structures thereon, the elongated structures having two sidewalls opposite each other, and wherein a strained layer of semiconductor material is on each sidewall.

In embodiments, step a may comprise providing a semiconductor substrate having one or more elongated structures thereon, the elongated structures having a top surface, and wherein a strained layer of semiconductor material is on each top surface.

In embodiments of the first aspect, the one or more elongated structures may be a plurality of parallel elongated structures, and every elongated structures may have a strained layer of semiconductor material on both sidewalls thereof and on the top wall thereof.

In embodiments, each elongated structure provided in step a may be formed of a stack of layers comprising two layers made of a first material separated by a layer made of a second material, thereby providing elongated structures having sidewalls which each comprises two surfaces made of the first material separated by a surface made of the second material. This splits each sidewall into at least two surfaces made of the first material. If the second material is less favourable to the formation of a layer of semiconductor material thereon than the first material, the at least two surfaces made of the first material will permit the formation of at least two nanowires stacked vertically, thereby increasing the number of nanowires which are formed per elongated structure.

In embodiments, each elongated structure provided in step a is formed of a stack of layers comprising two layers made of a first material separated by a layer made of a second material, thereby providing elongated structures having sidewalls which each comprises two surfaces made of the first material separated by a surface made of the second material, wherein a strained layer of semiconductor material is on each surface made of the first material.

In embodiments, the actual lattice constants of the monocrystalline surfaces of the first material may differ to a greater extent from the corresponding intrinsic lattice constants of the semiconductor material making up the strained layer than the actual lattice constants of the monocrystalline surfaces of the second material. This makes the second material less favourable to the formation of a layer of semiconductor material thereon than the first material. This way the layer of semiconductor material will preferably deposit on the first material, and if it deposits on both the first and second material, it will tend to migrate toward the first material upon annealing, leading to nanowires only on the surfaces made of the first material.

For instance, the actual lattice constants of the second material could be selected to differ by at least 5% and preferably by at least 6% from the intrinsic lattice constants of the semiconductor material making up the strained layer, while the actual lattice constants of the first material could be selected to differ by at most 5% and preferably by at most 4.5% from the intrinsic lattice constants of the semiconductor material making up the strained layer.

In embodiments, the surface made of the first material may have a first lattice constant and the surface made of the second material has a second lattice constant smaller than the first lattice constant.

In preferred embodiments, the actual lattice constants of the monocrystalline surface of second material may be smaller (e.g., by at least 0.5% or preferably by at least 1%) than the actual lattice constants of the monocrystalline surface of first material, and the actual lattice constant of the monocrystalline surface of first material may be smaller (e.g., by at least 1%) than the intrinsic lattice constant of the semiconductor material making up the layer. This permits the layer of semiconductor material to be compressively strained, which is favourable to the formation of a nanowire.

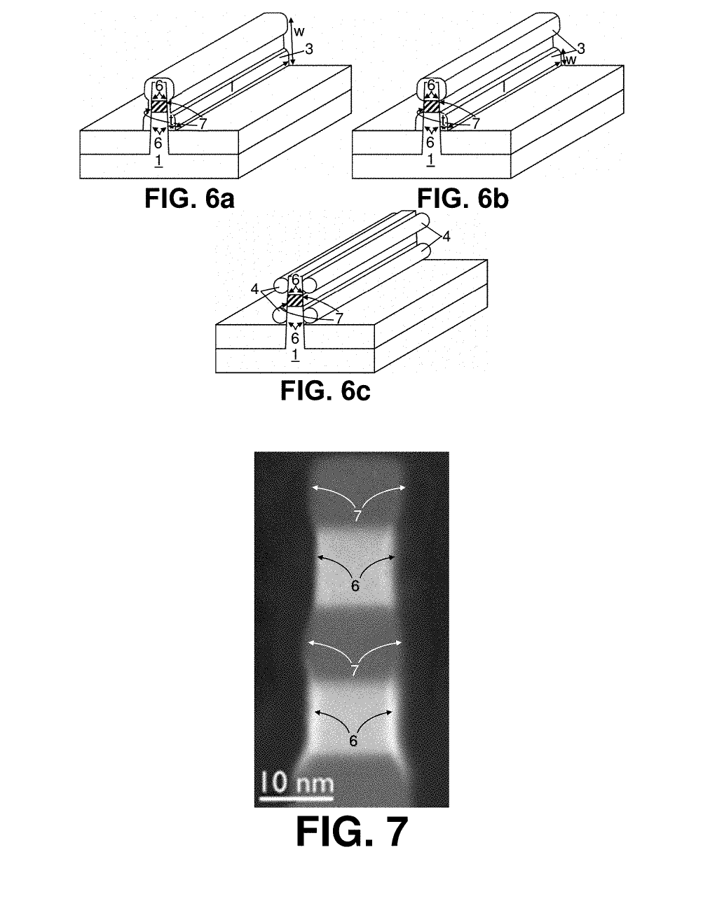

In some embodiments, when the elongated structure comprises a stack of layers, the step a2 (see infra) of epitaxially growing a strained layer of semiconductor material on the elongated structure may comprise growing the semiconductor material on both the monocrystalline surfaces of first material and the monocrystalline surfaces of second material (see, e.g., FIG. 6a). In other embodiments, the step a2 (see infra) of epitaxially growing a strained layer of semiconductor material on the elongated structure may comprise growing the semiconductor material only on the monocrystalline surfaces of first material, but not the monocrystalline surfaces of second material (see, e.g., FIG. 6b). The semiconductor material of the strained layer might for example not grow on the monocrystalline surfaces of second material when the difference between the intrinsic lattice constant of the semiconductor material forming the layer and the actual lattice constant of the second material is larger than 5%.

In embodiments, at least two of the two or more monocrystalline surfaces may be made of a first material having a first lattice constant difference with the semiconductor material and are separated from each other by at least one monocrystalline surface made of a second material having a second lattice constant difference with the semiconductor material; wherein the second material is chosen such that the second lattice constant difference is larger than the first lattice constant difference. The elongated structure may advantageously comprise monocrystalline surfaces of a first and second material, wherein contact to the second material constitutes a considerably larger potential energy for the semiconductor material as compared to contact to the first material. When this difference is large enough, it can advantageously be leveraged to move the semiconductor material away from the surfaces of second material upon reflow

Typically, the semiconductor material of the layer is a monocrystalline. In embodiments, the semiconductor material may be Si, Ge, SiGe or a III-V material. The III-V material may for example be InGaAs. A preferred material for the semiconductor material is Ge. It is particularly advantageous when grown on a monocrystalline surface made of SiGe.

In embodiments, the thickness (t) of the layer may be from 1 to 20 nm, preferably from 3 to 10 nm. A reflow of the semiconductor material may typically occur when the layer is sufficiently thin, such as 20 nm or smaller or 10 nm or smaller. It was found within the disclosed technology that a layer having a large thickness (t), e.g., thickness (t) of 100 nm or more, will typically be sufficiently stable and will not undergo reflow.

In embodiments, the width (w) of the layer may be from 5 to 50 nm. In embodiments, the ratio between the width (w) and the thickness (t) of the layer may be larger than 1, preferably larger than 3. In embodiments, the length (l) of the layer of semiconductor material may be from 10 to 60 nm, preferably from 15 to 50 nm, yet more preferably from 15 to 40 nm.

The layer of semiconductor material is strained. This can for instance be achieved by growing the layer on a monocrystalline surface having actual lattice constants different from the corresponding intrinsic lattice constants of the semiconductor material making the layer.

In embodiments, the at least a surface of the elongated structure may have one or both actual lattice constants differing by at least 1%, and preferably by at least 1.5% with the intrinsic lattice constant of the semiconductor material of the layer grown thereon. This is advantageous as it typically permits the layer to be sufficiently strained to form a nanowire upon annealing.

In the case where the elongated structure has at least a surface having two different lattice constants, it is sufficient for one of these two lattice constants to be different in the manner indicated supra, e.g., by 1% or more, for the layer of semiconductor grown thereon to be sufficiently strained to reflow upon annealing.

In embodiments, the at least a surface of the elongated structure may have actual lattice constants differing by at most 6%, and preferably by at most 5% with the intrinsic lattice constant of the semiconductor material of the layer grown thereon. This is advantageous as it typically permits the layer to actually grow on that surface. A difference of more than 6% can prevent pseudomorphic epitaxial growth.

Preferably, the layer of semiconductor material is compressively strained. This can for instance be achieved by growing the layer on a monocrystalline surface having at least one actual lattice constant which is smaller than the corresponding intrinsic lattice constant of the semiconductor material making the layer. This is preferably achieved by growing the layer on a monocrystalline surface having both its actual lattice constants smaller than the corresponding intrinsic lattice constants of the semiconductor material making the layer.

In the first aspect of the disclosed technology, relaxing the strained layer comprises annealing the strained layer. Optionally, in addition to the annealing step, reducing the pressure of the environment (e.g., chamber) in which the layer is present also helps relaxing the strained layer.

In embodiments, annealing the layer may comprise annealing the layer at a temperature below its melting temperature but above 100° C., preferably above 250° C., yet more preferably above 300° C., such as a temperature comprised in the range of from 300 to 600° C. The temperature used is adapted to the semiconductor material. It is chosen so that it is above the reflow temperature of the material, i.e., sufficiently high for the reflow to occur, under the given environmental circumstances (e.g., pressure). In embodiments, annealing the layer may comprise heating the layer at a temperature not surpassing 100° C. below the melting temperature of the semiconductor material the layer is made of, preferably not surpassing 200° C. below that melting temperature, yet more preferably not surpassing 400° C. below that melting temperature. It is an advantage of the disclosed technology that the formation of a nanowire via the reflow of the semiconductor material can be obtained at temperatures considerably below the melting temperature of the semiconductor material.

The annealing step may for example be provided during a subsequent processing step of the semiconductor device after providing the layer, such as for example during a subsequent gate stack formation.

In embodiments, changing the pressure of the environment in which the layer is present may comprise reducing the pressure in the environment to below 15 Torr, preferably to below 10 Torr. The substrate is typically provided under atmospheric pressure (760 Torr) and relaxing at least part of the layer can for instance be helped by reducing this pressure.

In embodiments, relaxing at least part of the layer by annealing the layer and optionally by additionally reducing the pressure of the environment in which the layer is present may be performed for 0.5 to 120 minutes, preferably for 1 to 60 minutes, yet more preferably for 2 to 20 minutes. It is an advantage of the disclosed technology that the formation of a nanowire via the reflow of the semiconductor layer can be obtained within a few minutes of relaxing the layer.

In embodiments of the disclosed technology, the annealing step b may have for effect of bringing its width/thickness ratio of the strained layer closer to 1. This gradually transforms the layer into a nanowire. Typically, the length of the layer does not change by more than 20%, not even by more than 10%, not yet even by more than 5% and most typically does not change at all during the annealing.

In embodiments, the at least a surface may be two or more surfaces and the semiconductor nanowire may be two or more semiconductor nanowires.

In embodiments, the nanowire may have a diameter of 4 to 25 nm, preferably 4 to 12 nm, yet more preferably 5 to 8 nm.

When a plurality of nanowires is obtained through the method according to embodiments of the first aspect, each nanowire may be located within 30 nm of another nanowire, preferably within 25 nm, yet more preferably within 20 nm, yet even more preferably within 10 nm and most preferably within 7 nm. As earlier described, embodiments of the disclosed technology allow a plurality of nanowires, such a plurality of nanowires per elongated structure (e.g., FIG. 5b or FIG. 5c), to be formed, wherein the nanowires are fixed in a position where they are spatially separated but still relatively close to one another.

In embodiments, the nanowire may be formed on the surface on which the strained layer was or on an adjacent surface. Formation of the nanowire on an adjacent surface is favoured if the surface on which the strained layer was has a width of less than 30 nm. Formation of the nanowire on an adjacent surface is also favoured if the surface on which the strained layer was formed has actual lattice constants differing more from the intrinsic lattice constants of the material making up the strained layer than the actual lattice constants of the adjacent layer differs from these same intrinsic lattice constants.

In embodiments, after the formation of the semiconductor nanowire, the method may further comprise selectively etching at least a part of the surface of the elongated structure on which the nanowire is present, with respect to the semiconductor material, in order to expose a region of the at least one semiconductor nanowire that was in contact with the surface prior to the etching. Selectively etching at least part of the elongated structure, said part comprising the surface (e.g., etching the whole elongated structure) with respect to the semiconductor material advantageously allows the nanowire to be transversally detached from the surface, e.g., subsequently allowing a gate-all-around type gate to be formed. For example, when the semiconductor material is SiGe and the elongated structure material is Si, then a selective etching of the elongated structure can be achieved using an HCl based etching. Preferably, the nanowire is attached to the substrate via connection of its extremities to a structural element not comprising the elongated structure. This is advantageous because after selective removal of the elongated structure, the nanowire may advantageously remain suspended through the attachment at its extremities (the distance between said extremities corresponding to the length of the nanowire), e.g., the nanowire may remain suspended between source and drain contacts.

In embodiments, the method may comprise a step e, after step b if no step c2 or d2 is present or after step c2 or d2 if present (see infra), of removing the elongated structures selectively with respect to the semiconductor nanowires.

The method of the disclosed technology can be used in the fabrication of a number of semiconductor device types. For instance, the nanowires obtained by the method may serve as interconnects in an integrated circuit. They may also be used as the channels from which a FET or a sensor can be fabricated. Sensors can make use of the nanowires obtained by the method according to the first aspect by measuring a change in conduction through the nanowire due to the influence of a chemical environment on the nanowire charge density. A particularly promising use of the method according to the first aspect is for fabricating a FET. A nanowire according to embodiments of the disclosed technology can advantageously be used as a channel material in a FET. Fabricating this FET may advantageously comprise forming a gate over a portion of the length of the nanowire by covering the nanowire with one or more gate materials. In some embodiments, the gate may be a gate-all-around-type gate. In some embodiments, the transistor may be an inversion-mode FET having a source and a drain of a first doping type and either an undoped channel or a channel of a second doping type opposite to the first doping type. In other embodiments, the transistor may be a junctionless transistor wherein the whole nanowire is doped with dopants of a same type so that source, drain and channel have the same doping type.

In some embodiments, formation of a gate may involve a replacement metal gate process.

In an embodiment aimed at forming a FET (e.g., either inversion-mode or junctionless), the first aspect may further comprise the steps of:
forming a gate stack comprising a gate dielectric and a gate electrode around a portion of the length of the nanowire comprised between the source and the drain regions.

In an embodiment aimed at forming an inversion-mode FET (also called MOSFET), the first aspect may further comprise the steps of:
forming a source region at one extremity of the nanowire and a drain region at the other extremity of the nanowire,
forming a gate stack comprising a gate dielectric and a gate electrode around a portion of the length of the nanowire.

In another embodiment aimed at forming a junctionless FET, the first aspect may further comprise the steps of:
uniformly doping the source, drain and channel region of the nanowire with dopants of a same type,
forming a gate layer comprising a gate dielectric and a gate electrode around a portion of the length of the nanowire comprised between the source and the drain regions.

In embodiments of the first aspect, a step of doping the nanowire may be performed. The nanowire are preferably doped after their formation but in some embodiments, it is possible to form doped strained layer, then to formed the doped nanowires by annealing these doped strained layers.

Doping the nanowire advantageously allows n- and/or p-type nanowires to be obtained.

In embodiments, the doping may be performed at the extremities of the nanowire to form a source and a drain region. In that case the channel present between the source and the drain region can be left undoped or can be doped with a polarity opposite to the polarity of the doping performed at the source and drain region. In such embodiments, a n-type or p-type nanowire will be a nanowire which source and drain are respectively n-type or p-type doped. This is typically the case in the fabrication of an inversion-mode FET.

In other embodiments, the doping may be performed uniformly along the length of the nanowire. In such embodiments, a n-type or p-type nanowire will be a nanowire which is respectively entirely n-type or p-type doped. This is typically the case in the fabrication of a junctionless FET.

In embodiments of the first aspect, forming a source region and a drain region may comprise doping the nanowire at its extremities.

Doping may in some cases be achieved through injection of dopants through the extremities of the nanowire. In other cases, conformal doping may be performed. Doping may be achieved through a multitude of different techniques, such as ion implantation or conformal doping via doped glass deposition.

In embodiments, a plurality of nanowires may be produced and the doping may be such that the plurality of nanowires comprises at least one n-type nanowire and at least one p-type nanowire. Doping a plurality of nanowires to obtain both n- and p-type nanowires can advantageously allow a CMOS device to be created at the active device level (cf. infra).

A further step in the formation of a FET is the formation of electrical contacts on the source region, drain region and gate.

In embodiments, the plurality of nanowires may comprise at least one n-type nanowire and at least one p-type nanowire. The spatial separation of the nanowires in the plurality of nanowires may be used to obtain both an n- and p-type doped nanowires. For example, the nanowires may be stacked, i.e., they may be present at different heights above the substrate, and nanowires at a first height may be subject to a first doping with e.g., a doped glass deposition, while, before uncovering the nanowires at the first height, nanowires at a second height may be subject a second doping with e.g., an ion implanting; thus allowing a plurality of nanowires with both n- and p-type doping to be obtained.

In embodiments, the method of the first aspect may comprise the steps of:
a1. providing a semiconductor substrate having one or more elongated structures thereon and a strained layer of a semiconductor material on at least a surface of the elongated structures,
b1. annealing the strained layer provided in step a1, thereby forming a semiconductor nanowire therefrom,
c1. Doping the semiconductor nanowire to form a semiconductor nanowire of a first doping type,
d1. after step c1, covering the semiconductor nanowire of a first doping type with a covering material while leaving at least another surface of the elongated structures exposed,
a2. after step d1, providing a strained layer of semiconductor material on the at least another surface of the elongated structures,
b2. annealing the strained layer provided in step a2, thereby forming a semiconductor nanowire therefrom,
c2. After step b2, doping the semiconductor nanowire to form a semiconductor nanowire of a second doping type opposite to the first doping type
d2. Removing the covering material.

In embodiments, the method of the first aspect may comprise the steps of:
a1. providing a semiconductor substrate having one or more elongated structures thereon and a strained layer of a semiconductor material of a first doping type on at least a surface of the elongated structures,
b1. annealing the strained layer of a first doping type provided in step a1, thereby forming a semiconductor nanowire of a first doping type therefrom,
c1. after step b1, covering the semiconductor nanowire of a first doping type with a covering material while leaving at least another surface of the elongated structures exposed,
a2. after step c1, providing a strained layer of semiconductor material of a second doping type opposite to the first doping type on the at least another surface of the elongated structures,
b2. annealing the strained layer of a second doping type provided in step a2, thereby forming a semiconductor nanowire of a second doping type therefrom, and
c2. Removing the covering material.

In embodiments, the method of the first aspect may comprise the steps of:
a1. providing a semiconductor substrate having one or more elongated structures thereon and a strained layer of a semiconductor material of a first doping type on at least a surface of the elongated structures,
a2. after step a1, covering the strained layer of a semiconductor material of a first doping type with a covering material while leaving at least another surface of the elongated structures exposed,
a3. after step a2, providing a strained layer of semiconductor material of a second doping type opposite to the first doping type on the at least another surface of the elongated structures,
a4. removing the covering material,
b. annealing the strained layers, thereby forming semiconductor nanowires therefrom.

A plurality of nanowires comprising both n- and p-type nanowires advantageously allows both n- and p-type FETs to be created and subsequently be connected into a CMOS device at the active device level, as opposed to the current limitation of needing to be connected at the middle- or back-end-of line level.

In a second aspect, the disclosed technology relates to an intermediate structure in the fabrication of a semiconductor device comprising a semiconductor substrate having a plurality of parallel elongated structures thereon and a semiconductor nanowire on corresponding surfaces of each of these parallel elongated structures.

In this second aspect, the semiconductor device, the semiconductor substrate, the plurality of parallel elongated structures and the semiconductor nanowire can be according to any embodiment of the first aspect.

In a third aspect, the disclosed technology relates to a semiconductor device comprising a plurality of parallel nanowires wherein each nanowire is located within 30 nm, preferably within 10 nm, yet more preferably within 7 nm of another nanowire.

In this third aspect, the semiconductor device and the plurality of parallel elongated structures can be according to any embodiment of the first aspect.

In preferred embodiments, the semiconductor device may comprise at least one n-type nanowire and at least one p-type nanowire.

In preferred embodiments, the plurality of parallel nanowires may be organized in different parallel nanowire layers, stacked on each other, and wherein at least one nanowire layer is composed of n-type nanowires and at least one nanowire layer is composed of p-type nanowires.

In a fourth aspect, the disclosed technology relates to a method for fabricating a semiconductor device, comprising:
a. Providing a stack of layers comprising a strained layer (3) of a first semiconductor material between two layers of a second semiconductor material,
b. removing part of the layers of the second semiconductor material at an extremity thereof, thereby reducing a contact area of the strained layer with the layers of the second semiconductor material, thereby freeing at least an extremity of the strained layer, said freed extremity extending from the stack, and
c. annealing the freed extremity.

In embodiments, the stack may comprise a plurality of strained layer of a first semiconductor material, each of these layers being between two layers of a second semiconductor material.

Like for the first aspect, it was surprisingly found within the fourth aspect of the disclosed technology that upon relaxing (i.e., upon reducing and preferably suppressing the strain) in an extremity of a layer of strained semiconductor material present on a substrate surface, the layer reflows (i.e., the semiconductor material rearranges spatially), while remaining in the solid state (i.e., without melting). In the present case, relaxing the extremity of the layer of strained semiconductor material was achieved by a combination of removing the original cause of the strain, i.e., the layer surface of the second material in contact with and underlying the extremity, and annealing. This effect could advantageously be used to form a nanowire-shaped structure from the extremity of the layer of semiconductor material by causing the freed extremity to reflow until a nanowire is formed.

The concept of the fourth aspect is also based on the reflow of a semiconductor material creating lateral nanowires at pitch defined by the width of a template (the layers of the second semiconductor material). The width of the nanowire-shaped extremities is preferably such that charge carriers are confined therein by charge confinement effect. This can be achieved for instance with a width of less than 12 nm and preferably less than 10 nm for InGaAs, less than 8 nm for Ge, and less than 4 nm for Si. An advantage of this aspect of the embodiments is that there is no need for detaching the nanowire-shaped features from the rest of the layer. The nanowire-shaped features produced by the fourth aspect can be used as interconnects or can be used as channel as indicated for any embodiment of the first aspect.

In the fourth aspect, the strained layer of the first semiconductor material may be as indicated as suitable for forming the strained layer in any embodiment of the first aspect.

In the fourth aspect, the second semiconductor material may be a material indicated as suitable for forming the elongated structure in any embodiment of the first aspect. The thickness of the layers of a second semiconductor material may be from 1 to 20 nm and preferably from 3 to 10 nm. A low thickness for the layer of a second semiconductor material is advantageous as it permits the nanowires formed from two successive layers of a first semiconductor material to be separated by no more than said thickness. This permits each nanowire-shaped feature formed in the fourth aspect to be located within 20 nm, preferably within 10 nm or even within 7 nm of another nanowire.

In embodiments, the extremity freed in step b may have a width to thickness ratio of from 3 to 1, preferably from 1.5 to 1.

Step c of annealing the freed extremity typically results in a rounded free extremity. Rounding the free extremity typically comprises, if the freed extremity has a width to thickness ratio above 1, bringing this ratio closer to 1. Rounding the free extremity also typically comprises, if the freed extremity has a cross-section taken perpendicularly to its length, said cross section having a perimeter, reducing the largest distance between the geometrical center of the cross-section and the point of the perimeter farther away from the center and increasing the smallest distance between the geometrical center of the cross-section and the point of the perimeter closest to the geometrical center.

In embodiments, the method may further comprise a step d of removing the rest of the layers of the second semiconductor material.

In a fifth aspect, the disclosed technology relates to a semiconductor device comprising a stack of layers comprising a layer of a first semiconductor material between layers of a second semiconductor material, wherein at least an extremity of the layer of a first semiconductor material extends from the stack and is rounded.

In this fifth aspect, the first semiconductor material may be a layer of a material indicated as suitable for forming the strained layer in any embodiment of the first aspect and the second semiconductor material may be a material indicated as suitable for forming the elongated structures in any embodiment of the first aspect. Typically, the layer of first semiconductor material is strained where it contacts the layer of second semiconductor material but relaxed at its extremity extending from the stack.

The invention will now be described by a detailed description of several embodiments of the invention. It is clear that other embodiments of the invention can be configured according to the knowledge of the person skilled in the art without departing from the true technical teaching of the invention, the invention being limited only by the terms of the appended claims.

### EXAMPLE 1

### Formation of Strained Layers on a Strained Fin

With reference to FIG. 1, a substrate 1 is provided, e.g., a Si wafer, comprising a crystalline structure 1a, and an optional isolation region such as a shallow trench isolation regions 1b formed therein. The crystalline structure 1a has a first lattice constant L₁ in all directions (both in directions parallel and perpendicular to the substrate top surface) according to some embodiments in which the crystalline structure 1a is formed of a first material having a cubic crystal structure, e.g., a diamond cubic crystal structure such as the crystal structure of silicon. For example, if the crystalline structure 1a is formed of a Si wafer, L₁ is 5.42 Å. Subsequently, a fin 11 of a second semiconductor material, e.g., Si_{0.75}Ge_{0.25}, is epitaxially grown on the top surface of the crystalline structure 1a, where the second material adopts the first lattice constant L₁ in a direction parallel to the top surface of the crystalline structure 1a, while having a second lattice constant L₂ in a direction perpendicular to the top surface of the crystalline structure 1a. If the second semiconductor material is Si_{0.75}Ge_{0.25}. e.g., which has an intrinsic lattice constant of 5.48 Å, the second lattice constant L₂ can have the value of 5.52 Å. The second material provides the monocrystalline surfaces 2a, 2b on which a strained layer 3 of a third semiconductor material is subsequently grown. It is noteworthy that the second material is itself strained and offers different lattice constants on its top surface (e.g., a single lattice constant of 5.42 Å) and its side surfaces (e.g., a first lattice constant equal 5.42 Å and a second lattice constant equal 5.52 Å). The semiconductor surface 2b corresponding to the top surface of the fin 11 has the same (unique, since it is a square lattice) lattice constant as the top surface of the crystalline structure 1a (e.g., both lattice constants equal 5.42 Å), while the semiconductor surface 2a has two different lattice constants, one which is parallel to the top surface of the crystalline structure la (e.g., 5.42 Å), and which is equal to the first lattice constant L₁, and one which is perpendicular to the top surface of the crystalline structure 1a and which is equal to the second lattice constant L₂ (e.g., 5.52 Å). Subsequently, the layer 3 of the third semiconductor material, e.g., Ge (intrinsic lattice constant equal 5.66 Å), is epitaxially grown as a strained layer on the fin. The actual lattice constants of the third semiconductor material, e.g., Ge, depend on which surface 2a or 2b of the fin the material is grown on:
the first lattice constant L₁ and the second lattice constant L₂ parallel to the semiconductor surface 2a on which it is grown and L₃ perpendicularly to that semiconductor surface 2a,
the first lattice constant L1 for the two directions parallel to the semiconductor surface 2b on which it is grown and the fourth lattice constant L₄ perpendicularly to that surface. It is to be noted that in the case of the Si/SiGe/Ge system exemplified here, since the differences (0.24 Å and 0.24 Å) between the intrinsic lattice constants of the further material (e.g., 5.66 Å for each of the two relevant constants) and the lattice constants of the top surface 2b of the fin (e.g., 5.42 Å for each of the two constants) are larger than the differences (0.24 Å and 0.10 Å) between the intrinsic lattice constants of the further material (e.g., 5.66 Å for each of the two relevant constants) and the lattice constants of the sidewalls (5.42 Å and 5.52 Å), the layer of strained material will preferentially form nanowires on the sidewalls. The reason for this is that the layer of material will prefer to form on the surface where it is less strained, and the layer of material formed on the surface where it is more strained will tend to migrate, upon annealing, toward adjacent surfaces where it is less strained. This migration to adjacent surfaces depends also on the width of the more strained surface: the smaller this width, the more likely the migration to an adjacent surface. This phenomenon could be observed when the width of the fin was 15 nm as in the following Example 2:

### EXAMPLE 2

### Formation of Nanowires Against a Fin

FIGS. 2a and 2b are electron micrographs illustrating the formation of nanowires on a fin structure, according to embodiments. The fin structure includes a substrate 1 includes a SiO₂ shallow trench isolation layer (STI) formed in a Si base substrate. An epitaxial Si_{0.75}Ge_{0.25} fin is grown on top of the Si base substrate and a thin Ge layer 3 is epitaxially grown on top of the fin. The epitaxial growth of Ge was performed at 350° C. using GeH₄ with a deposition time of about 2 min to obtain a 10 nm thick layer (FIG. 2a). Subsequently, the structure was annealed at 350° C. for several minutes, leading to a reflow of the Ge layer 3 to form two Ge nanowires 4, each on a side 2 of the fin (FIG. 2b).

### EXAMPLE 3

### Formation of a Nanowire Against a Sidewall of a Fin

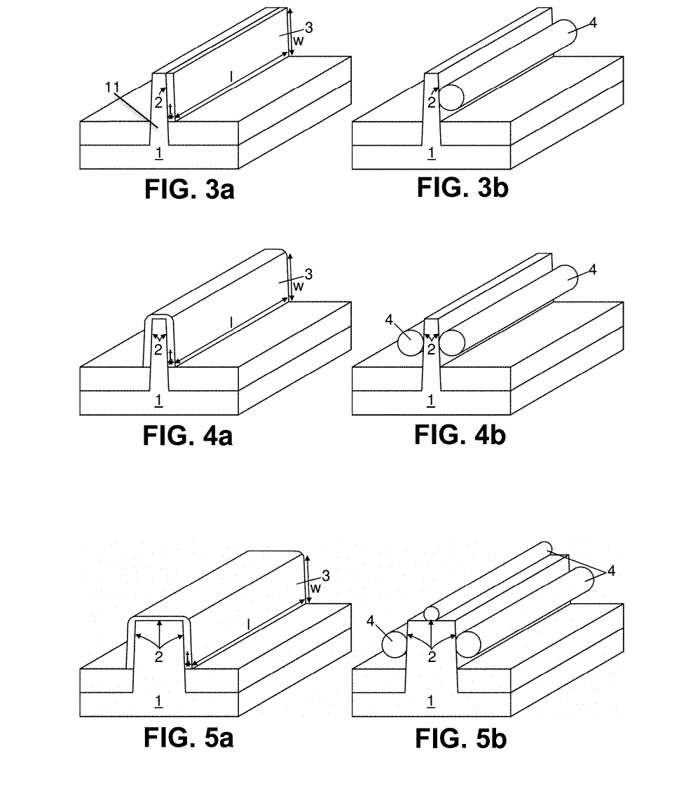

FIGS. 3a-3b illustrate formation of a nanowire on a side surface of a fin structure, according to embodiments. FIG. 3a illustrates a substrate 1 on which a fin 11 is epitaxially grown has a strained layer 3 of semiconductor material on a side surface 2 of the fin 11, according to embodiments. The layer is depicted with its thickness (t), width (w) and length (l). FIG. 3b illustrates formation of a nanowire 4 on the side surface 2 upon annealing the strained layer 3, according to embodiments.

### EXAMPLE 4

### Formation of a Nanowires from Strained Layers Present on Each Wall of a Fin

FIGS. 4a-4b and 5a-5b illustrate formation of nanowire on surfaces of a fin structure, according to embodiments. In FIG. 4a, layers of strained semiconductor material are provided on the top surface 2 and both of the side surfaces 2 of a thin fin having a width of less than about 30 nm. In FIG. 5a, layers of strained semiconductor material are provided on the top surface 2 and both side surfaces 2 of a fin having a width of more than 30 nm. After annealing, a nanowire 4 is formed on the side surfaces 2 only in the case FIG. 4b and on both side surfaces 2 and the top surface 2 in the case of FIG. 5b.

### EXAMPLE 5

### Formation of a Fin Comprising Surfaces (2) of Different Materials

FIG. 7 illustrates formation of a fin structure having surfaces formed of different materials, according to embodiments. Referring to FIG. 7, alternating layers of a first material 6 (e.g., SiGe) and a second material 7 (e.g., Si) were epitaxially grown on a Si substrate 1, which was prepared using ion implantation; using SiH₄ and GeH₄ as precursors and an N₂/H₂ carrier gas below 20 Torr for the epitaxial growth. The obtained SiGe layers 6 contained about 30% Ge, using growth temperatures above 600° C. SiGe/Si fins were subsequently patterned in the SiGe/Si layers by sidewall image transfer, and the STI trenches were filled with an oxide.

### EXAMPLE 6

### Formation of Nanowires Stacked Vertically

FIGS. 6a-6c illustrate formation nanowires on a fin structure having surfaces formed of different materials, according to embodiments. A film of semiconductor material 3, such as Ge, is grown over fins formed of a stack of layers comprising two layers made of a first material 6 separated by a layer made of a second material 7. This is depicted in FIGS. 6a and 6b. The stack can, for instance, be obtained using a process similar to that described above with respect to Example 5. In FIG. 6a, the layer of semiconductor material 3 (e.g., Ge) grew on both the first material 6 and the second material 7 but grew thicker on the first material. This can occur for instance when the second material 7 (e.g., Si_{0.70}Ge_{0.30}) has lattice constants not too different from the lattice constant of the first material 6 (e.g., Si), e.g., for a low Ge content such as the 30% obtained in Example 5. To obtain SiGe layers 6 containing a higher proportion of Ge, a lower temperature is preferably used to avoid intermixing and Si₂H₆ (or Si₃H₈) and Ge₂H₆ are preferably used as precursors. FIG. 6b shows the situation where the layer of semiconductor material 3 grew only on the first material. This can for instance occur when the second material 7 has lattice constants far apart from the lattice constants of the first material 6. We now turn to FIG. 6c. After annealing, nanowires 4 are formed only on the surfaces made of the first material 6, this independently of the presence or absence of the semiconductor material layer 3 on the second material 7.

### EXAMPLE 7

### Forming Nanowires of a First and a Second Polarity with a Pitch Twice Larger for the Nanowires of a First or Second Polarity.

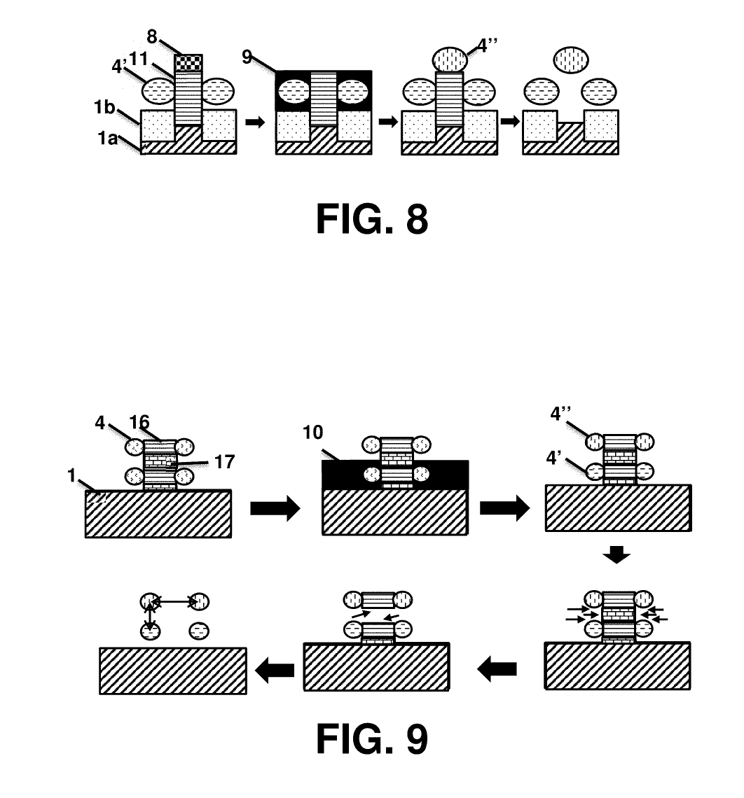

We now refer to the FIG. 8. A substrate 1 formed of a SiO₂ shallow trench isolation layer (STI) 1b and of a Si base 1a is provided. A SiN hard mask 8 is provided on top of the fin 11 to mask its top surface. After annealing, nanowires 4 are formed. A Si_{0.50}Ge_{0.50} fin 11 is epitaxially grown on top of the Si base 1a and a thin Ge layer (not shown) is epitaxially grown on top of the fin. Subsequently, the structure is annealed at a temperature and for a time sufficient to reflow the Ge layer 3 to form two Ge nanowires 4, each on a side of the fin 11. Next, the nanowires 4 are doped by conformal doping or ion implantation. Next, an interlayer 9 is deposited and planarized by chemical mechanical polishing (CMP) to expose the top surface of the fin 11. After a cleaning step, a silicon layer is deposited on the top surface of the fin 11. Then, this Si layer is annealed and a Si nanowire 4′ is formed. Next, this nanowire 4′ is doped with a dopant type opposite to the dopant type doping the Ge nanowires. Next, the interlayer is removed. Next, the p-type and the n-types nanowires are released by removing the fin.

### EXAMPLE 8

### Formation of Parallel Nanowire Layers of Alternating Doping Type

We now refer to FIG. 9. We start with a structure analogous to FIG. 6c of example 6 which is represented at the top left of FIG. 9. Next, the nanowire 4 layer closest to the substrate is doped by conformal doping with dopants of a first type, thereby forming a doped nanowire 4′ layer of a first type. This is performed via the use of a doped glass layer 10 covering that nanowire 4 layer. Next, the nanowire layer farthest from the substrate is doped by ion implantation, thereby forming a doped nanowire 4″ layer of a second type. The resulting structure is the second structure at the top of FIG. 9. Next, the glass layer 10 is removed. This is depicted on the top right of FIG. 9. Next, the fin 16, 17 is removed, freeing the sidewalls of the doped nanowires 4′, 4″. The nanowires 4′, 4″ can be indirectly anchored to the substrate 1 via e.g., attachment to source and drain contacts (not shown).

### EXAMPLE 9

### Relaxing Free Extremities Extending Form a Stack of Layers

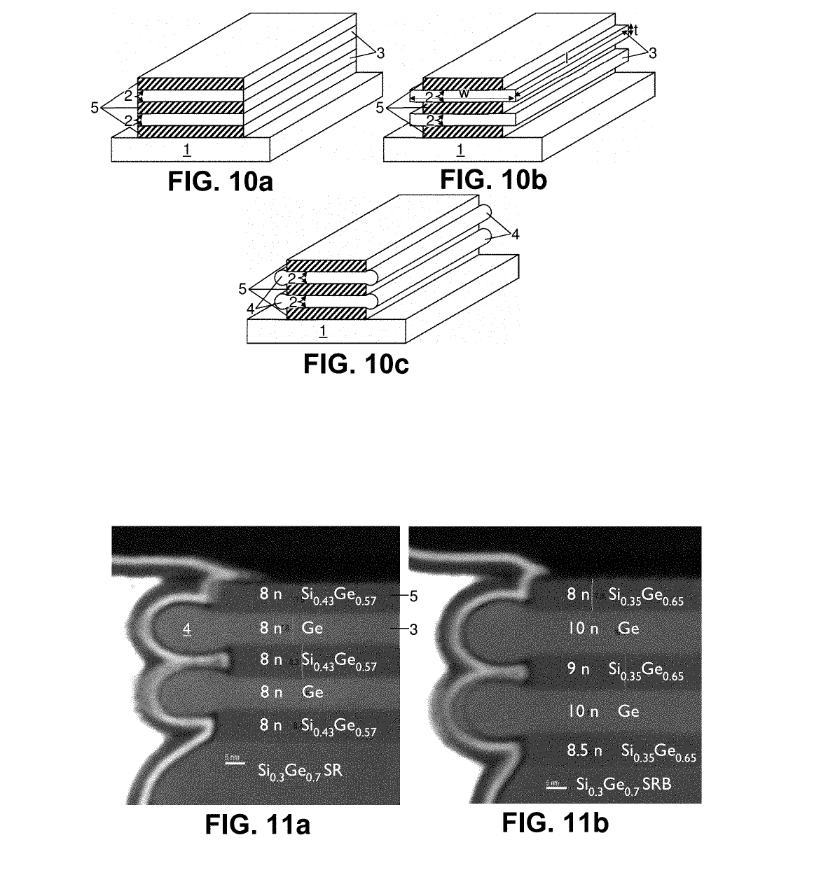

We now refer to FIGS. 10a-10c. In this embodiment, the layer of semiconductor material is a layer 3 comprised in a stack of layers. The stack of layers may comprise layers 3 of semiconductor material alternated with layers of a further material 5 having at least one monocrystalline surface 2. The layer 3 is in contact with a monocrystalline surface 2 at its bottom, its top, or both (FIG. 10a). Relaxing part of the layer in such a case may comprise removing part of the layers 5, thereby reducing a contact area of the layer with the monocrystalline surfaces 2, thereby forming at least one free extremity, i.e., an end portion of the layer which is not in contact with the further material 5, extending from the stack (FIG. 10b). Removing part of the layers 5 combined with annealing typically results in a reflow of the semiconductor material in the freed extremity, leading to the formation of a nanowire-shaped feature 4 attached to the remainder of the layer in the stack (FIG. 10c). In embodiments, the stack of layers wherein the layer has a free extremity extending therefrom may be obtained from a stack of layers, having no such extending free extremity (FIG. 10a) and subsequently selectively recessing the further material 5 with respect to the layer (FIG. 10b). Wherein selectively recessing the further material 5 consists of at least partially removing the further material 5, from a side of the stack inwards, thereby reducing the contact area of the layer with at least one monocrystalline surface 2. In embodiments, relaxing the layer may comprise reducing the contact area of the layer with the at least one second layer 2 by means of the selective recessing, combined with annealing.

We now refer to FIGS. 11a and 11b. A stack of Si_{0.43}Ge_{0.57} (FIG. 11a) or Si_{0.35}Ge_{0.65} (FIG. 11b) layers 5, alternated with Ge layers 3, was grown on a Si_{0.3}Ge_{0.7} strain relaxed buffer (SRB). The SiGe 5 was partially recessed, selectively with respect to the Ge layers 3, thereby yielding Ge layers 3 having free extremities extending from the stack. As earlier explained (e.g., see FIGS. 10a-10c), this selective recessing in turn triggered upon annealing a relaxation of the free extremities, forming nanowires 4 attached to the remainder of the Ge layers 3.

It is to be understood that although preferred embodiments, specific constructions and configurations, as well as materials, have been discussed herein for devices according to the present invention, various changes or modifications in form and detail may be made without departing from the scope and technical teachings of this invention. For example, any formulas given above are merely representative of procedures that may be used. Functionality may be added or deleted from the block diagrams and operations may be interchanged among functional blocks. Steps may be added or deleted to methods described within the scope of the present invention.

What is claimed is:

1. A method of fabricating a semiconductor device, the method comprising:
providing a semiconductor substrate comprising one or more elongated structures formed thereon, the one or more elongated structures extending in a first lateral direction, each of the one of more elongated structures having at least one surface on which a strained layer of semiconductor material is formed; and
annealing the strained layer to form a semiconductor nanowire on the at least one surface of the each of the one or more elongated structures.

2. The method according to claim 1, wherein annealing the strained layer reduces an area of contact between the strained layer and a respective surface of a respective elongated structure, thereby forming the semiconductor nanowire.

3. The method according to claim 1, wherein the one or more elongated structures comprise a plurality of parallel elongated structures extending in the first lateral direction, and wherein each of the elongated structures has a strained layer of semiconductor material formed on a corresponding surface.

4. The method according to claim 1, wherein each of the one or more elongated structures has opposing sidewalls, and wherein a strained layer of semiconductor material is formed on each of the opposing sidewalls.

5. The method according to claim 1, wherein each of the one or more elongated structures comprises a sidewall and a top surface, and wherein a strained layer of semiconductor material is formed on the top surface.

6. The method according to claim 1, wherein each of the one or more elongated structures has a top surface on which a first strained layer of semiconductor material is formed, and has a side surface on which a second strained layer of semiconductor material is formed, wherein the first strained layer and the second strained layer have different lattice constants in a second lateral direction and in a vertical direction.

7. The method according to claim 1, further comprising:
doping the semiconductor nanowire with a first dopant type;
after doping the semiconductor nanowire, covering the semiconductor nanowire with a covering material while leaving at least another surface of the one or more elongated structures exposed;
after covering the semiconductor nanowire, forming a second strained layer of semiconductor material on the at least another surface of the one or more elongated structures;
annealing the second strained layer of semiconductor material to form a second semiconductor nanowire on the at least the another surface of the each of the one or more elongated structures;
after annealing to forming the second semiconductor nanowire, doping the second semiconductor nanowire with a second dopant type opposite to the first dopant type; and
removing the covering material.

8. The method according to claim 1, wherein the each of the one or more elongated structures is formed of a stack of layers comprising two layers formed of a first material separated by a layer formed of a second material, thereby providing the each of the elongated structures having opposing sidewalls, wherein each of the opposing sidewalls comprises two surfaces formed of the first material separated by a surface formed of the second material, wherein the strained layer of semiconductor material is formed on each of the two surfaces formed of the first material.

9. The method according to claim 8, wherein the two surfaces formed of the first material has a first lattice constant, and wherein the surface formed of the second material has a second lattice constant smaller than the first lattice constant.

10. The method according to claim 1, further comprising selectively removing the each of the one or more elongated structures with respect to the semiconductor nanowire formed thereon.

11. The method according to claim 1, wherein the strained layer is compressively strained.

12. The method according claim 1, wherein a plurality of strained layers is formed from which a plurality of nanowires are formed, the method further comprising doping one or both of the plurality of strained layers and the plurality of nanowires, such that the at least one n-type nanowire and at least one p-type nanowire are formed.

13. The method according claim 1, wherein a plurality of strained layers is formed, and wherein a plurality of nanowires are formed, wherein each of the nanowires is formed within a distance of 30 nm or smaller relative to an adjacent one of the nanowires.

14. An intermediate structure of a semiconductor device formed according to the method according to claim 3, the intermediate structure comprising the semiconductor substrate comprising the plurality of parallel elongated structures and the semiconductor nanowire formed on a corresponding surface of the each of the one or more parallel elongated structures according to claim 3.

15. A semiconductor device comprising a plurality of parallel nanowires, wherein each one of the parallel nanowires is formed within a distance of 30 nm or smaller of another one of the parallel nanowires, wherein the parallel nanowires are organized on different parallel nanowire layers stacked on each other, and wherein at least one of the parallel nanowire layers comprises an n-type nanowire organized thereon and at least one of the parallel nanowire layers comprises a p-type nanowire organized thereon.

16. A method of fabricating a semiconductor device, comprising:
providing a stack of layers comprising a strained layer formed of a first semiconductor material being formed between two layers formed of a second semiconductor material;
removing end portions of each of the two layers formed of the second semiconductor material to reduce a contact area between the strained layer and each of the two layers of the second semiconductor material, thereby forming end portions of the strained layer extending beyond the end portions of each of the two layers formed of the second semiconductor material; and
annealing the end portions of the strained layer.

17. The method according to claim 16, further comprising removing remaining portions of each of the two layers of the second semiconductor material.
